(19) United States
(12) Patent Application Publication
(10) Pub. No.: US 2026/0136856 A1
(43) Pub. Date: May 14, 2026

(54) METHOD AND SYSTEM FOR FORMING SILICON NITRIDE ON A SIDEWALL OF A FEATURE

(71) Applicant: ASM IP Holding B.V., Almere (NL)

(72) Inventors: Tomohiro Kubota, Tokyo (JP); Shinya Ueda, Tokyo (JP)

(21) Appl. No.: 19/440,747

(22) Filed: Jan. 6, 2026

Related U.S. Application Data
(62) Division of application No. 17/449,670, filed on Oct. 1, 2021, now Pat. No. 12,550,644.
(60) Provisional application No. 63/088,078, filed on Oct. 6, 2020.

(51) Int. Cl. H10P 14/694; H10P 14/60; H10P 14/692; H10P 50/28

(52) U.S. Cl. CPC H10P 14/69433; H10P 14/6336; H10P 14/6339; H10P 14/6532; H10P 14/6682; H10P 14/69215; H10P 50/283

(57) ABSTRACT

Methods of forming silicon nitride on a sidewall of a feature are disclosed. Exemplary methods include providing a substrate comprising a feature comprising a sidewall surface and a surface adjacent the sidewall surface, forming a silicon oxide layer overlying the sidewall surface and the surface adjacent the sidewall surface, using a cyclical deposition process, depositing a silicon nitride layer overlying the silicon oxide layer, and exposing the silicon nitride layer to activated species generated from a hydrogen-containing gas. Exemplary methods can additionally include selectively removing a portion of the silicon nitride layer. Structures formed using the methods and systems for performing the methods are also disclosed.

### CROSS-REFERENCE TO RELATED APPLICATIONS

This application is a divisional of, and claims priority to, U.S. patent application Ser. No. 17/449,670 filed Oct. 1, 2021 titled METHOD AND SYSTEM FOR FORMING SILICON NITRIDE ON A SIDEWALL OF A FEATURE; which claims priority to U.S. Application No. 63/088,078, filed on Oct. 6, 2020 in the United States Patent and Trademark Office, the disclosures of which are incorporated herein in their entirety by reference.

### FIELD OF INVENTION

The present disclosure generally relates to methods and systems for forming devices. More particularly, examples of the disclosure relate to methods and systems for forming silicon nitride on surfaces of a substrate.

### BACKGROUND OF THE DISCLOSURE

Silicon nitride layers can be used for a variety of applications during the formation of electronic devices. For example, silicon nitride layers can be used as dielectric layers, diffusion barriers, hard masks, spacers, and the like.

In some applications, it may be desirable to form silicon nitride primarily on sidewall surfaces of features, such that no or relatively little silicon nitride remains on surfaces adjacent the sidewalls (e.g., top and bottom surfaces). One technique to form silicon nitride on the sidewall surfaces includes depositing a thin conformal layer of silicon nitride, treating portions of the silicon nitride layer, and selectively removing the treated silicon nitride using a wet etch process. This technique can result in blistering and/or delamination of the silicon nitride layer, particularly on surfaces adjacent the sidewall surface, after treatment and before selectively removing portions of the silicon nitride layer. The blistering and/or delamination can cause unwanted removal and/or removal variation of the silicon nitride material from or near the bottom of the vertical sidewall surfaces. The unwanted removal of the silicon nitride material can, in turn, lead to unwanted variation in the silicon nitride material remaining on vertical surfaces and/or device performance. The delamination and blistering can become increasingly problematic as a thickness of the silicon nitride layer decreases (e.g., to less than 20 nm or less than 10 nm).

Another technique to form silicon nitride on the sidewall surfaces includes using high radiofrequency (RF) power during the deposition of the silicon nitride layer overlying features, and using a wet etch process to remove the silicon nitride on the surface adjacent the sidewall surface. However, such techniques often result in undesirably high amounts of the silicon nitride layer being removed near the intersection of the sidewall and the adjacent surface(s).

Accordingly, improved methods of forming silicon nitride on sidewall surfaces of features are desired. Further, structures, such as structures suitable for forming devices, which include the silicon nitride and systems for forming the structures, are also desired.

Any discussion of problems and solutions set forth in this section has been included in this disclosure solely for the purpose of providing a context for the present disclosure, and should not be taken as an admission that any or all of the discussion was known at the time the invention was made.

### SUMMARY OF THE DISCLOSURE

Various embodiments of the present disclosure relate to methods of forming silicon nitride on sidewalls of features, to systems for forming silicon nitride on sidewalls of features, and to structures including the silicon nitride on the sidewalls. The silicon nitride can be used in the formation of devices, such as semiconductor devices.

While the ways in which various embodiments of the present disclosure address drawbacks of prior methods, systems, and structures are discussed in more detail below, in general, various embodiments of the disclosure provide improved methods of forming silicon nitride on vertical surfaces. The methods can result in less blistering and/or delamination of the silicon nitride on or near bottom surfaces of features. Thus, silicon nitride films formed on sidewall surfaces can include desired material remaining at a bottom corner of the features. Further, techniques described herein can result in less variation of silicon nitride formed on sidewall surfaces, which can result in better and more predictable device performance.

In accordance with exemplary embodiments of the disclosure, a method of forming silicon nitride on a sidewall of a feature is provided. One or more exemplary methods include the steps of providing a substrate within a reaction chamber, the substrate comprising a feature comprising a sidewall surface and a (e.g., bottom) surface adjacent the sidewall surface; forming a silicon oxide layer overlying the sidewall surface and the adjacent surface; using a cyclical deposition process, depositing a silicon nitride layer overlying the silicon oxide layer; and exposing the silicon nitride layer to activated species generated from a hydrogen-containing gas. Exemplary methods can also include a step of selectively removing a portion of the silicon nitride layer overlying the surface adjacent the sidewall surface relative to a portion of the silicon nitride layer overlying the sidewall surface. In accordance with various examples of the disclosure, the cyclical deposition process includes providing a silicon precursor and providing a nitrogen reactant. In accordance with further examples of the disclosure, the cyclical deposition process comprises a plasma-enhanced cyclical deposition process. The step of selectively removing can include a wet etch process or a dry etch process. The wet etch process can include use of an HF-based aqueous solution, such as an aqueous HF solution or an aqueous solution comprising HF and NH₄F. The dry etch process can include use of activated species formed from a plasma generated from gases that contain fluorine, such as NF₃, SF₆, CF₄, and the like. The step of forming a silicon oxide layer can include one or more ALD, CVD, PVD, thermal oxidation, rapid thermal oxidation, coating, plasma oxidation, radical oxidation, or the like.

In accordance with further embodiments of the disclosure, a structure is provided. The structure can be formed according to a method as set forth herein. The structure can include a substrate having one or more features, each including a vertical surface or sidewall and silicon nitride overlying the sidewall.

In accordance with further examples of the disclosure, a device comprises or is formed using a structure as described herein.

In accordance with yet additional examples of the disclosure, a system configured to perform a method and/or form a structure as described herein is provided.

These and other embodiments will become readily apparent to those skilled in the art from the following detailed description of certain embodiments having reference to the attached figures; the invention not being limited to any particular embodiment(s) disclosed.

### BRIEF DESCRIPTION OF THE DRAWING FIGURES

A more complete understanding of exemplary embodiments of the present disclosure can be derived by referring to the detailed description and claims when considered in connection with the following illustrative figures.

FIG. 1 illustrates a silicon nitride film formed overlying a substrate, wherein the silicon nitride layer is delaminated from a surface of the substrate.

FIG. 2 illustrates a method in accordance with at least one embodiment of the disclosure.

FIG. 3 illustrates a timing sequence for a method in accordance with examples of the disclosure.

FIGS. 4-8 illustrate structures in accordance with embodiments of the disclosure.

FIGS. 9 and 10 illustrate additional structures in accordance with examples of the disclosure.

FIG. 11 illustrates a system in accordance with at least one embodiment of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The present disclosure generally relates to methods of forming silicon nitride on a sidewall of a feature, to structures including a silicon nitride layer, and to systems for performing the methods and/or forming the structures. As described in more detail below, various methods can be used to form structures including silicon nitride on a sidewall surface of a feature, with desired silicon nitride remaining at the bottom of the sidewall/feature. Additionally or alternatively, silicon nitride on the sidewall surface can be formed in a more predictable manner and/or device performance can be improved.

In this disclosure, gas may include material that is a gas at normal temperature and pressure, a vaporized solid and/or a vaporized liquid, and may be constituted by a single gas or a mixture of gases, depending on the context. For example, a precursor or reactant gas can include a precursor or reactant and an inert gas. A gas other than the process gas, i.e., a gas introduced without passing through a gas distribution assembly, such as a showerhead, other gas distribution device, or the like, may be used for, e.g., sealing the reaction space, and may include a seal gas, such as a rare or other inert gas. The term inert gas refers to a gas that does not take part in a chemical reaction to an appreciable extent and/or a gas that can excite a precursor when plasma power is applied. The terms precursor and reactant can be used interchangeably.

As used herein, the term substrate can refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as GaAs, and can include one or more layers overlying or underlying the bulk material. Further, the substrate can include various features, such as recesses, lines, protrusions, and the like formed within or on at least a portion of a layer of the substrate. By way of particular examples, a substrate can include bulk semiconductor material having features formed therein or thereon.

In some embodiments, film refers to a layer extending in a direction perpendicular to a thickness direction to cover an entire target or concerned surface, or simply a layer covering a target or concerned surface. In some embodiments, layer refers to a structure having a certain thickness formed on a surface or a synonym of film or a non-film structure. A layer can be continuous or noncontinuous. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequences, and/or functions or purposes of the adjacent films or layers. In some cases, a portion of a layer or film can be removed (e.g., by etching); the remaining portion of the film or layer may be referred to as a layer or film.

In this disclosure, continuously can refer to one or more of without breaking a vacuum, without interruption as a timeline, without any material intervening step, without changing treatment conditions, immediately thereafter, as a next step, or without an intervening discrete physical or chemical structure between two structures other than the two structures in some embodiments.

The term cyclic deposition process or cyclical deposition process can refer to the sequential introduction of precursors (and/or reactants) into a reaction chamber to deposit a layer over a substrate and includes processing techniques such as atomic layer deposition (ALD), cyclical chemical vapor deposition (cyclical CVD), and hybrid cyclical deposition processes that include an ALD component and a cyclical CVD component.

As used herein, the term atomic layer deposition (ALD) may refer to a vapor deposition process in which deposition cycles, preferably a plurality of consecutive deposition cycles, are conducted in a process chamber. Typically, during each cycle, a precursor is introduced and may be chemisorbed to a deposition surface (e.g., a substrate surface or a previously deposited underlying surface such as material from a previous ALD cycle), forming a monolayer or sub-monolayer that does not readily react with additional precursor (i.e., a self-limiting reaction). Thereafter, a reactant (e.g., another precursor or reaction gas) may subsequently be introduced into the process chamber for use in converting the chemisorbed precursor to the desired material on the deposition surface. Typically, this reactant is capable of further reaction with the precursor. Further, purging steps may also be utilized during each cycle to remove excess precursor from the process chamber and/or remove excess reactant and/or reaction byproducts from the process chamber after conversion of the chemisorbed precursor. Further, the term atomic layer deposition, as used herein, is also meant to include processes designated by related terms, such as chemical vapor atomic layer deposition, atomic layer epitaxy (ALE), molecular beam epitaxy (MBE), gas source MBE, or organometallic MBE, and chemical beam epitaxy when performed with alternating pulses of precursor composition(s), reactive gas, and purge (e.g., inert carrier) gas. PEALD refers to an ALD process, in which a plasma is applied during one or more of the ALD steps.

As used herein, silicon oxide refers to a material that includes silicon and oxygen. Silicon oxide can be represented by the formula SiOₓ, where x can be between 1 and 2 (e.g., SiO₂). In some cases, the silicon oxide may not include stoichiometric silicon oxide. In some cases, the silicon oxide can include other elements, such as carbon, nitrogen, hydrogen, or the like.

As used herein, silicon nitride refers to a material that includes silicon and nitrogen. In some cases, the silicon nitride may not include stoichiometric silicon nitride. In some cases, the silicon nitride can include other elements, such as carbon, oxygen, hydrogen, or the like.

Further, in this disclosure, any two numbers of a variable can constitute a workable range of the variable, and any ranges indicated may include or exclude the endpoints. Additionally, any values of variables indicated (regardless of whether they are indicated with about or not) may refer to precise values or approximate values and include equivalents, and may refer to average, median, representative, majority, or the like in some embodiments. Further, in this disclosure, the terms include, including, constituted by and having can refer independently to typically or broadly comprising, consisting essentially of, or consisting of in some embodiments. In this disclosure, any defined meanings do not necessarily exclude ordinary and customary meanings in some embodiments.

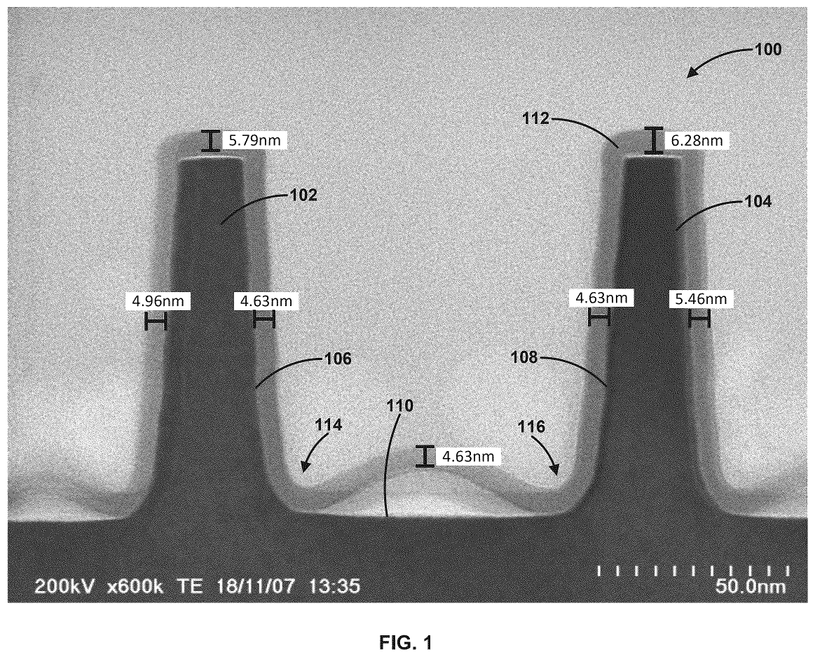

Turning now to the figures, FIG. 1 illustrates a structure 100, including features 102 and 104 and a silicon nitride layer 112 formed overlying features 102 and 104. Feature 102 includes a vertical surface or sidewall 106 and feature 104 includes a vertical surface or sidewall 108. A bottom, horizonal surface 110 spans between features 102 and 104. As illustrated, silicon nitride layer 112 is delaminated on bottom surface 110. Such delamination can occur during, for example, treatment of silicon nitride layer 112. During a subsequent etch of silicon nitride layer overlying bottom surface 110, undesired variation in material removal in regions 114 and 116 can occur. Examples of the disclosure mitigate or eliminate such delamination and blistering.

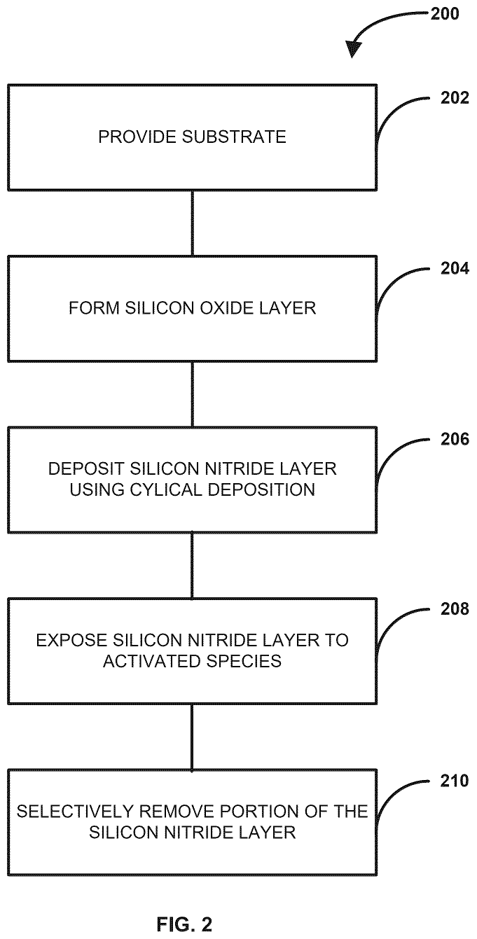

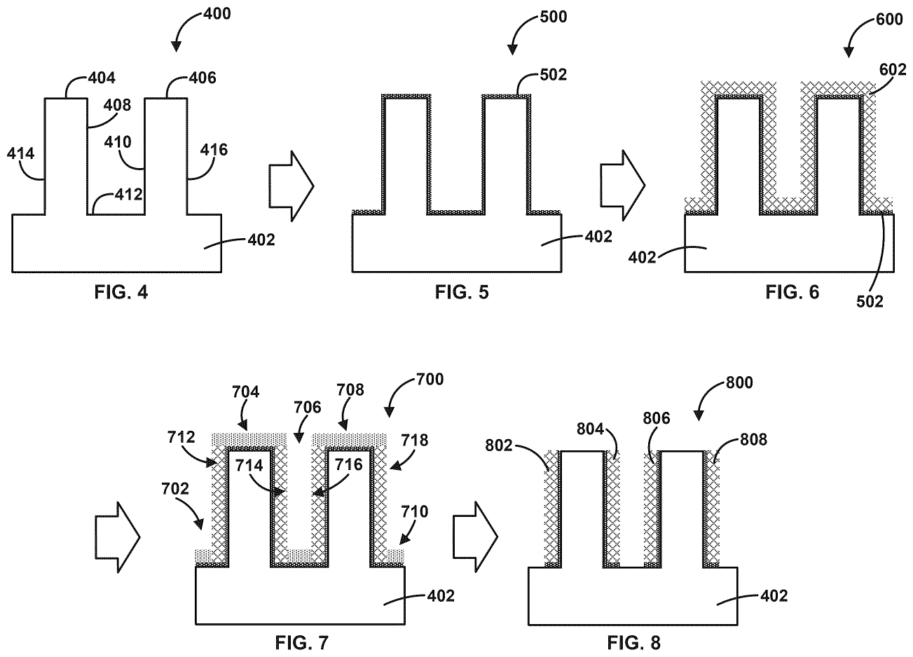

FIG. 2 illustrate a method 200 in accordance with examples of the disclosure. FIGS. 4-8 illustrate structures formed along various steps of method 200.

Method 200 includes the steps of providing a substrate within a reaction chamber (step 202), forming a silicon oxide layer (step 204), using a cyclical deposition process, depositing a silicon nitride layer (step 206), exposing the silicon nitride layer to activated species (step 208), and selectively removing a portion of the silicon nitride layer overlying the surface adjacent the sidewall surface relative to a portion (step 210). Unless stated otherwise, methods in accordance with the disclosure need not include all steps of method 200 illustrated in FIG. 2.

During step 202, a substrate (e.g., substrate 402, illustrated in FIG. 4) or a structure 400 is provided. The substrate can include any of the material described above. In accordance with aspects of the disclosure, the substrate includes features (e.g., features 404, 406) comprising sidewall surfaces (e.g., sidewall surfaces 408, 410, 414, 416) and a surface (e.g., a bottom surface 412) adjacent the sidewall surface. By way of examples, the substrate can include bulk semiconductor (e.g., silicon) material.

During step 204, a silicon oxide layer (e.g., silicon oxide layer 502, illustrated in FIG. 5) is formed on a surface of the substrate to form a structure 500. For example, the silicon oxide layer can be formed overlying the sidewall surface and the bottom surface of the substrate. The silicon oxide layer can be formed using any suitable method, such as one or more of ALD, CVD, PVD, thermal oxidation, rapid thermal oxidation, coating, plasma oxidation, radical oxidation, or the like. A thickness of the silicon oxide layer can be greater than 1.5 nm, greater than 2 nm, or greater than 2.8 nm and/or is less than 50 nm, less than 10 nm, or less than 5 nm. In some cases, the thickness of the silicon oxide is greater than 1.1 nm or greater than 1.5 nm to effectively prevent or mitigate delamination.

During step 206, a silicon nitride layer (e.g., silicon nitride layer 602) is formed overlying the silicon oxide layer (e.g., silicon oxide layer 502) to form a structure 600. Step 206 can begin with loading a substrate onto a susceptor within a reaction chamber. Once the substrate is loaded onto the susceptor, a gate valve can be closed. In some cases, the susceptor can be moved to an operating position. A temperature of a susceptor and/or within a reaction chamber during step 206 can be between about 200° C. and about 600° C., about 300° C. and about 550° C., or about 350° C. and about 500° C. Similarly, a pressure within the reaction chamber may be controlled to provide a reduced atmosphere in the reaction chamber for subsequent processing. For example, the pressure within the reaction chamber can be between about 200 Pa and about 6000 Pa, about 350 Pa and about 4000 Pa, or about 400 Pa and about 3000 Pa.

Using a cyclical deposition process, depositing a silicon nitride layer step 206 can include providing a silicon precursor and providing a nitrogen reactant to the reaction chamber.

Exemplary silicon precursors for use with step 206 include one or more of alkylaminosilanes, aminosilanes, halosilanes. By way of examples, the silicon precursor can comprise one or more precursors selected from the group consisting of bisdiethylaminosilane (BDEAS), bisdimethylaminosilane (BDMAS), hexylethylaminosilane (HEAD), tetraethylaminosilane (TEAS), tert-butylaminosilane (TBAS), bistert-butylaminosilane (BTBAS), bisdimethylaminodimethylaminosilane (BDMADMS), heptametyldisilazane (HMDS), trimethysylyldiethlamine (TMSDEA), trimethylsyledimethlamine (TMSDMA), trimethyltoribinylcycletrisilazane (TMTVCTS), tristrimetylhydroxyamine (TTMSHA), bisdimethylsaminomethylsilane (BDMAMS), dimetyhlsilyldimethlamine (DMSDMA), silane, SiXH₃ or SiX₂H₂ or SiX₃H or SiX₄ where X is one of Cl, Br, I, XH₂Si—SiXH₂ or X₂HSi—SiX₂H or X₃Si—SiX₃ where X is one of Cl, Br, I.

Exemplary nitrogen reactants for use with step 206 include, for example, one or more reactants selected from the group consisting of nitrogen and ammonia or the like. The reactant can be provided to the reaction chamber with an inert gas. For example, the reactant can be coflowed to the reaction chamber with an inert gas, such as one or more of argon and helium.

Depositing a silicon nitride layer step 206 can be or include a plasma-enhanced cyclical deposition process. The plasma-enhanced cyclical deposition process can be or include a direct plasma process. A plasma power during step 206 can be between about 300 W and about 2000 W, about 500 W and about 1500 W, or about 700 W and about 1000 W.

A thickness of the silicon nitride can be, for example, between about 2 nm and about 30 nm, about 3 nm and about 20 nm, or about 4 nm and about 10 nm.

Once the silicon nitride layer has been formed to a desired thickness, during step 208, the silicon nitride layer (e.g., layer 602) can be exposed to activated species generated from a hydrogen-containing gas to form a structure (e.g., structure 700, illustrated in FIG. 7). The hydrogen-containing gas can include, for example, hydrogen and an inert gas comprising one or more of nitrogen, argon, and helium. A volumetric ratio of the hydrogen to inert gas can range from, for example, about 1 to about 20 or about 10 to about 0.

The activated species can be generated from, for example, a direct plasma within a reaction chamber. Plasma conditions during step 208 can be selected, such that the activated species are directional and can preferentially interact with silicon nitride layer 602 on horizonal surfaces to form transformed regions 702-710. Transformed regions 702-710 may be relatively easy to etch, compared to silicon nitride material in regions 712-718, namely overlying sidewalls 408, 410, 414, and 416. By way of examples, a plasma frequency during step 208 can be between about 10 MHz and about 2.5 GHZ. A plasma power during step 208 can be between about 500 W and about 2000 W, about 600 W and about 1500 W, or about 700 W and about 1000 W.

During step 210, a structure (e.g., structure 700) can be exposed to an etch process to selectively remove transformed regions 702-710, while other portions of the silicon nitride layer (e.g., portions 802-808) remain on the structure (e.g., structure 800), as illustrated in FIG. 8. As used herein, selective or selectively etching can mean that the etch rate of silicon nitride transformed regions 702-710 is higher (e.g., 2, 5, or 10 or more times higher) than the etch rate of silicon nitride material in regions 712-718.

The etch process can include a wet etch process and/or a dry etch process. The wet etch process can include, for example, use of a dilute hydrofluoric acid, alone or in combination with NH₄F. The dry etch can include, for example, a plasma generated from a gas that contains one or more fluorine-containing gases, such as NF₃, SF₆, and CF₄.

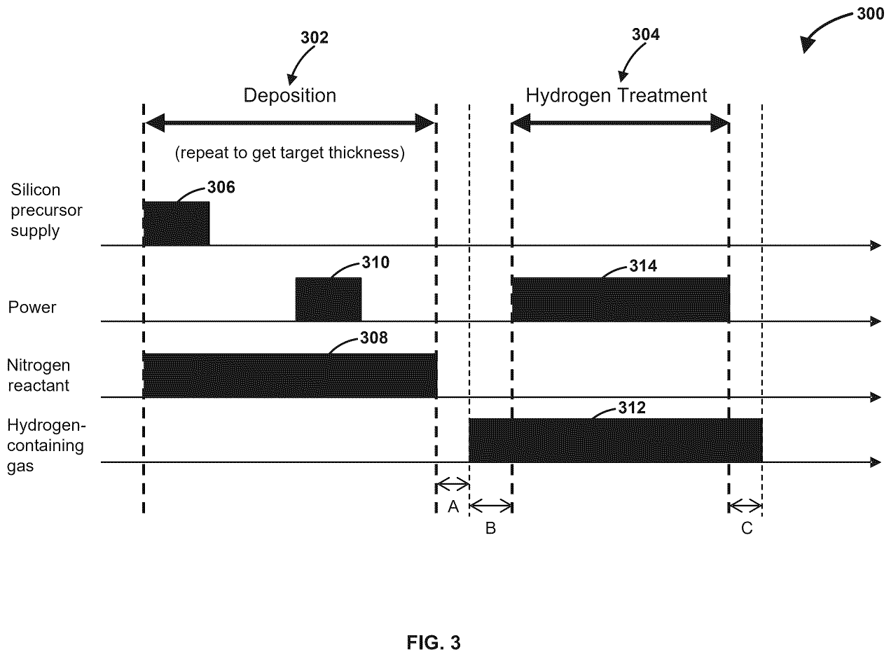

FIG. 3 illustrates a timing sequence 300 suitable for various methods and/or method steps of the discourse, including, for example, steps 206 and 208 of method 200. Timing sequence 300 includes one or more cyclical deposition cycles 302 and one or more hydrogen treatment steps 304. One or more cyclical deposition cycles can be repeated a number of times (e.g., between about 50 and about 5000 times)—e.g., to obtain a desired film thickness prior to hydrogen treatment step 304. As further illustrated, timing sequences in accordance with examples of the disclosure can include a rest period A, a stabilization period B, and/or a hydrogen flow period C.

In the illustrated example, timing sequence 300 includes a silicon precursor pulse period 306, a reactant pulse period 308, and a deposition plasma pulse period 310, a hydrogen-containing gas period 312, and a treatment plasma pulse period 314. As used herein, pulse period means a period in which a gas (e.g., precursor, reactant, inert gas, and/or carrier gas) is flowed to a reaction chamber and/or a period in which power is applied (e.g., power to produce a plasma). A height and/or width of the illustrated pulse period is not necessarily indicative of a particular amount or duration of a pulse.

Table 1 below illustrates exemplary ranges for flowrates, plasma power, and other parameters for pulse periods 306-312, B and C, which may be the same or similar to various conditions described above in connection with steps 206, 208 of method 200.

TABLE 1
Conditions for Steps206, 208/Pulse Periods 306-312, B, and C

| | |
|---|---|
| Deposition Reaction Chamber | Between about 200 Pa and about |
| Pressure | 6000 Pa, about 350 Pa and about |
| | 4000 Pa, or about 400 Pa and about |
| | 3000 Pa |
| Susceptor and/or reaction chamber | Between about 200° C. and about |
| temperature | 600° C., about 300° C. and about |
| | 550° C., or about 350° C. and about |
| | 500° C. |
| Flow rate of silicon precursor | 500-3500 sccm, 1000-3000 sccm, or |
| | 1500-2500 sccm (flow rate of carrier |
| | N2 gas which is introduced to |
| | precursor bottle) |
| Flowrate of nitrogen reactant | 1000-9000 sccm, 3000-7000 sccm, |
| | or 4000-6000 sccm (except for |
| | carrier N2 gas described above) |
| Flowrate of sealing gas | 10-300 sccm, 20-200 sccm, or 50- |
| | 150 sccm |
| Direct plasma power (Deposition) | Between 300 W and about 2000 W, |
| | about 500 W and about 1500 W, or |
| | about 700 W and about 1000 W |
| Distance between electrodes | 5-30 mm, 7-20 mm, or 10-14 mm |
| Duration of precursor pulse 306 | 0.5-5 sec, 0.7-2 sec, or 0.9-1.2 Sec |
| Duration of plasma period 310 | 1-6 sec, 2-5 sec, or 3-4 sec |
| Treatment Reaction Chamber | Between about 100 Pa and about |
| Pressure | 500 Pa, about 200 Pa and about |
| | 450 Pa, or about 300 Pa and about |
| | 400 Pa |
| Hydrogen-containing gas flowrate | 100-5000 sccm, 500-2000 sccm, or |
| | 800-1500 sccm |
| Duration of hydrogen-containing | Duration of period 304 plus 0-20 |
| gas pulse 312 | sec |
| Direct plasma power (Treatment) | Between 500 W and about 2000 W, |
| | about 600 W and about 1500 W, or |
| | about 700 W and about 1000 W |
| Duration of plasma period 314 | 20-200 sec, 30-100 sec, or 40-70 |
| | sec |
| Plasma Frequency for periods 310 | 10 kHz-2.45 GHz |
| and/or 314 | |

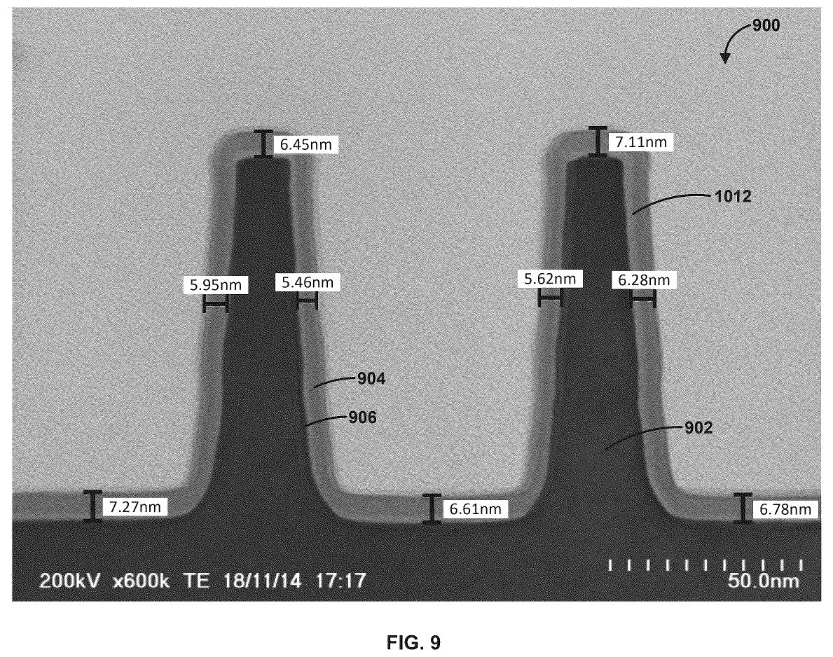

FIG. 9 illustrates a transmission electron micrograph of a structure 900, including a treated silicon nitride layer 904 overlying a silicon oxide layer 906 and a substrate 902. As illustrated and in contrast to the example illustrated in FIG. 1, silicon nitride layer 904 does not exhibit any blistering or delamination from substrate 902.

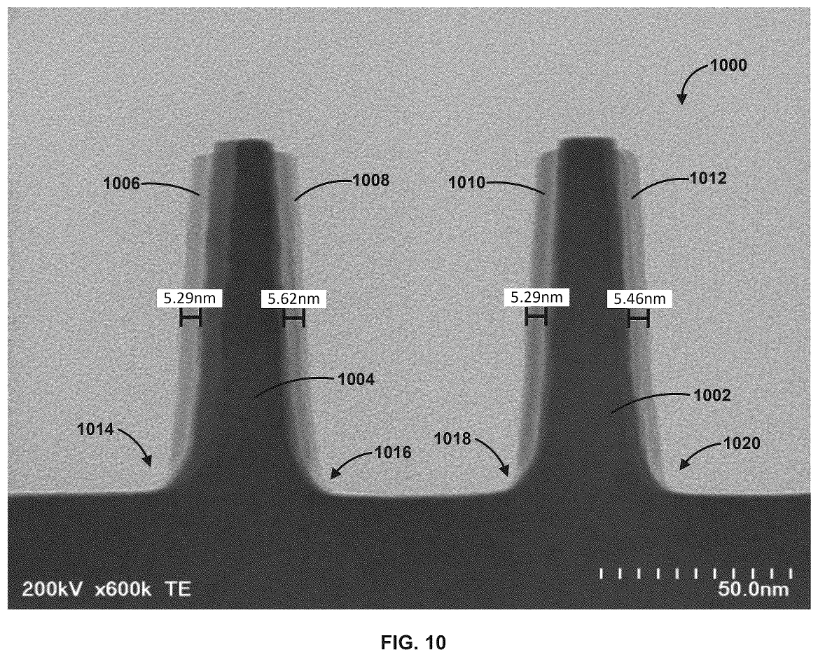

FIG. 10 illustrates transmission electron micrograph of a structure 1000 after a selective etch (e.g., step 210). As illustrated, structure 1000 includes features 1002 and 1004 including silicon nitride 1006, 1008, 1010, and 1012, respectively, formed thereon. The silicon nitride was formed overlying a silicon oxide layer, as described above. As illustrated, silicon nitride remains in regions 1014-1020, thus providing desired structure properties and device performance.

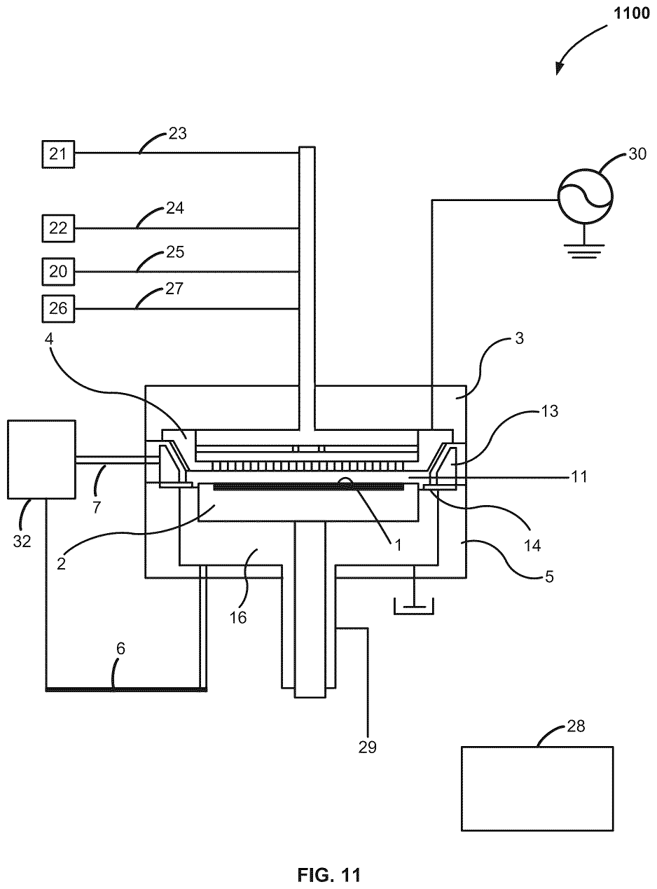

Turning now to FIG. 11, a reactor system 1100 is illustrated in accordance with exemplary embodiments of the disclosure. Reactor system 1100 can be used to perform one or more steps or substeps as described herein and/or to form one or more structures or portions thereof as described herein.

Reactor system 1100 includes a pair of electrically conductive flat-plate electrodes 4, 2 in parallel and facing each other in the interior 11 (reaction zone) of a reaction chamber 3. Although illustrated with one reaction chamber, system 1100 can include two or more reaction chambers. A plasma can be excited within reaction chamber 3 by applying, for example, HRF power (e.g., 100 kHz, 13.56 MHz, 27 MHz, 2.45 GHZ, or any values therebetween) from plasma power source 30 to one electrode (e.g., electrode 4) and electrically grounding the other electrode (e.g., electrode 2). A temperature regulator can be provided in a lower stage 2 (the lower electrode), and a temperature of a substrate 1 placed thereon can be kept at a desired temperature, such as the substrate temperatures noted above. Electrode 4 can serve as a gas distribution device, such as a shower plate or showerhead. Precursor gases, reactant gases, and a carrier or inert gas, if any, or the like can be introduced into reaction chamber 3 using one or more of a gas line 23, a gas line 24, a gas line 25, or a gas line 27 from sources 21, 22, 20, and 26, respectively, and through the shower plate 4. Although illustrated with four gas lines 23, 24, 25, and 27, reactor system 1200 can include any suitable number of gas lines. By way of examples, source 21 can correspond to a precursor source (e.g., comprising one or more of silicon precursors), source 22 can correspond to a nitrogen reactant source, source 20 can correspond to a hydrogen-containing gas source, and source 26 can correspond to an inert gas source.

In reaction chamber 3, a circular duct 13 with an exhaust line 7 can be provided, through which gas in the interior 11 of the reaction chamber 3 can be exhausted. Additionally, a transfer chamber 5, disposed below the reaction chamber 3, can be provided with a seal gas line 29 to introduce seal gas into the interior 11 of the reaction chamber 3 via the interior 16 (transfer zone) of the transfer chamber 5, wherein a separation plate 14 for separating the reaction zone and the transfer zone can be provided (a gate valve through which a substrate is transferred into or from the transfer chamber 5 is omitted from this figure). The transfer chamber can also be provided with an exhaust line 6 coupled to exhaust source 32. In some embodiments, continuous flow of a carrier gas to reaction chamber 3 can be accomplished using a flow-pass system (FPS).

Reactor system 1100 can include one or more controller(s) 28 programmed or otherwise configured to cause one or more method steps as described herein to be conducted. Controller(s) 28 are coupled with the various power sources, heating systems, pumps, robotics and gas flow controllers, or valves of the reactor, as will be appreciated by the skilled artisan. By way of example, controller 28 can be configured to control gas flow of a precursor, a reactant, and an inert gas into at least one of the one or more reaction chambers to form a silicon nitride layer on a surface of a substrate (e.g., comprising a silicon oxide layer). The controller can be further configured to provide activated species generated from a hydrogen-containing gas to the silicon nitride layer.

In some embodiments, a dual chamber reactor (two sections or compartments for processing substrates disposed close to each other) can be used, wherein a reactant gas and a noble gas can be supplied through a shared line, whereas a precursor gas is supplied through unshared lines.

The example embodiments of the disclosure described above do not limit the scope of the invention, since these embodiments are merely examples of the embodiments of the invention. Any equivalent embodiments are intended to be within the scope of this invention. Indeed, various modifications of the disclosure, in addition to the embodiments shown and described herein, such as alternative useful combinations of the elements described, may become apparent to those skilled in the art from the description. Such modifications and embodiments are also intended to fall within the scope of the appended claims.

What is claimed is:

1. A system comprising:
one or more reaction chambers;
a precursor source comprising a silicon precursor;
a nitrogen reactant source comprising a nitrogen reactant;
a hydrogen-containing gas source comprising a hydrogen-containing gas;
a plasma power source;
an exhaust source; and
a controller,
wherein the controller is configured to control gas flow of the silicon precursor and a nitrogen reactant into at least one of the one or more reaction chambers to perform a method to form a silicon nitride layer overlying a silicon oxide layer, the method comprising the steps of
providing a substrate comprising a feature comprising a sidewall surface and a surface adjacent the sidewall surface;
forming the silicon oxide layer overlying the sidewall surface and the surface adjacent the sidewall surface;
using a cyclical deposition process, depositing the silicon nitride layer overlying the silicon oxide layer;
generating activated species from the hydrogen-containing gas; and
exposing the silicon nitride layer to the activated species generated from the hydrogen-containing gas;
wherein the activated species preferentially interact with the silicon nitride layer on horizontal surfaces relative to the sidewall surface.

2. The system of claim 1, wherein the cyclical deposition process comprises:
providing the silicon precursor; and
providing the nitrogen reactant.

3. The system of claim 1, wherein the silicon precursor comprises one or more of an alkylaminosilane, an aminosilane, or a halosilane.

4. The system of claim 1, wherein the silicon precursor comprises one or more of bisdiethylaminosilane (BDEAS), bisdimethylaminosilane (BDMAS), hexylethylaminosilane (HEAD), tetraethylaminosilane (TEAS), tert-butylaminosilane (TBAS), bistert-butylaminosilane (BTBAS), bisdimethylaminodimethylaminosilane (BDMADMS), heptamethyldisilazane (HMDS), trimethysylydiethylamine (TMSDEA), trimethylsyledimethlamine (TMSDMA), trimethyltoribinylcycletrisilazane (TMTVCTS), tristrimethylhydroxyamine (TTMSHA), bisdimethylaminomethysilane (BDMAMS),
dimethylsilylydimethylaminedimetyhlsilyldimethlamine (DMSDMA), silane, SiXH₃ or SiX₂H₂ or SiX₃H or SiX₄ where X is one of Cl, Br, I, XH₂Si—SiXH₂ or X₂HSi—SiX₂H or X₃Si—SiX₃ where X is one of Cl, Br, I.

5. The system of claim 1, wherein the nitrogen reactant comprises one or more of nitrogen or ammonia.

6. The system of claim 1, wherein the controller is configured to provide a reactant gas comprising the nitrogen reactant and an inert gas to the one or more reaction chambers.

7. The system of claim 6, wherein the inert gas comprises one or more of argon and helium.

8. The system of claim 1, wherein the cyclical deposition process comprises a plasma-enhanced cyclical deposition process.

9. The system of claim 1, wherein the hydrogen-containing gas comprises hydrogen and an inert gas.

10. The system of claim 9, wherein the inert gas comprises one or more of nitrogen, argon, or helium.

11. The system of claim 1, wherein the method further comprises using a selective etch process, selectively removing the silicon nitride layer and the silicon oxide layer from the horizontal surfaces.

12. The system of claim 11, wherein the step of selectively removing comprises using a dry etch process.

13. The system of claim 1, wherein the one or more reaction chambers are configured to form a direct plasma.

14. The system of claim 1, wherein the controller is configured to generate activated species from the hydrogen-containing gas using a direct plasma.

15. The system of claim 1, wherein the plasma power source is coupled to an electrode within a reaction chamber of the one or more reaction chambers.

16. The system of claim 1, wherein the plasma power source is coupled to a showerhead within a reaction chamber of the one or more reaction chambers.

17. The system of claim 16, wherein another electrode within the reaction chamber is grounded.

18. The system of claim 1, wherein the plasma power source is configured to provide power of between about 500 W and about 2000 W.

19. The system of claim 1, wherein the plasma power source is configured to provide power of between 300 W and about 2000 W during the step of generating activated species from a hydrogen-containing gas.

20. The system of claim 1, wherein the controller is further configured to perform a stabilization period prior to the step of exposing the silicon nitride layer to the activated species generated from a hydrogen-containing gas.
